(19) United States
(12) Patent Application Publication
(10) Pub. No.: US 2001/0027552 A1
(43) Pub. Date: Oct. 4, 2001

(54) CD-ROM decoder

(76) Inventors: Takayuki Suzuki, Gifu-shi (JP); Hiroyuki Tsuda, Ichinomiya-shi (JP)

Correspondence Address: Douglas W. Swartz, SHERIDAN ROSS P.C., 1560 Broadway, Suite 1200, Denver, CO, 80202-5141, US

(21) Appl. No.: 09/818,051

(22) Filed: Mar. 27, 2001

(30) Foreign Application Priority Data
Mar. 28, 2000 (JP) 2000-088210

(51) Int. Cl. G11C 29/00

(52) U.S. Cl. 714/769

(57) ABSTRACT

A CD-ROM decoder that reduces the load on a microcomputer temporarily stores in a buffer memory in sector units digital data having a predetermined number of bytes and a predetermined format. The CD-ROM decoder also processes the digital data by selectively correcting and detecting code errors included in the digital data. A sector information conversion circuit identifies a mode of a sector of the digital data based on header information and compares former four bytes and latter four bytes of sub-header information to identify a form of the sector of the digital data.

### BACKGROUND OF THE INVENTION

The present invention relates to a CD-ROM decoder, and more particularly, to a CD-ROM decoder for correcting code errors included in digital data and transferring the corrected digital data to a computer.

FIG. 1 is a schematic block diagram of a prior art CD-ROM system 100. The CD-ROM system 100 includes a pickup 2, an analog signal processor 3, a digital signal processor 4, a CD-ROM decoder 5, a buffer RAM 6, and a microcomputer 7.

A spiral record track is defined on a disc 1. Digital data complying with a predetermined format is recorded along the record track. The digital data is generated through eight to fourteen modulation (EFM). The disc 1 is rotated at a constant linear velocity or a constant angular velocity.

The pickup 2 emits a laser beam against the disc 1 and generates from the reflected laser beam a voltage signal corresponding to the digital data recorded on the disc 1.

The analog signal processor 3 shapes the waveform of the voltage signal in correspondence with the fluctuation of the voltage signal provided from the pickup 2 to generate an EFM signal.

The digital signal processor 4 performs EFM demodulation on the EFM signal provided from the analog signal processor 3 to covert the 14-bit digital data to 8-bit digital data and generates CD-ROM data. Further, the digital signal processor 4 uses a cross interleave Reed-Solomon code (CIRC) to detect and correct code errors. A frame is defined by 24 bytes of CD-ROM data. With reference to FIG. 2, a sector is defined by 2,352 (98 frames×24) bytes of CD-ROM data. A synchronization signal (12 bytes) and a header (4 bytes) are allocated to the head of each sector. The synchronization signal has a fixed pattern and indicates the head of each sector. Absolute time information (minutes/seconds/frame number: each 1 byte) and a mode identification code (1 byte) are included in the header. The absolute time information corresponds to an address on the disc 1. The mode identification code is used to identify the format (mode) of the data in a sector. In accordance with the mode and form, user data, an error correction code (ECC), and an error detection code (EDC) are allocated to the 2,336 bytes following the header. For example, referring to FIG. 3, in mode 1, the user data (2,048 bytes), the EDC (4 bytes), ZERO (8 bytes), and the ECC (276 bytes) follow the header. In mode 2 formless, only the user data (2,336 bytes) follows the header. In form 1 of mode 2, a sub-header (8 bytes), user data (2,048 bytes), the EDC (4 bytes), and the ECC (276 bytes) follow the header. In form 2 of mode 2, the sub-header (8 bytes), the user data (2,334 bytes), and the EDC (4 bytes) follow the header.

The CD-ROM decoder 5 also corrects error codes included in the CD-ROM data provided from the digital signal processor 4 and transfers CD-ROM data (user data) to a host computer based on a request from the host computer.

The buffer RAM 6 is connected to the CD-ROM decoder 5 to store CD-ROM data in sector units for a predetermined time. The CD-ROM decoder 5 performs decoding to correct code errors in the CD-ROM data during the predetermined time.

The microcomputer 7 executes a predetermined control program so that the analog signal processor 3, the digital signal processor 4, and the CD-ROM decoder 5 are operated at predetermined timings. In response to a transfer request of the CD-ROM data from the host computer, the microcomputer 7 controls the analog signal processor 3, the digital signal processor 4, and the CD-ROM decoder 5 to transfer the requested data to the host computer.

The microcomputer 7 recognizes a flag bit of the transfer request command from the host computer and determines the transfer byte number per sector from the format of the transfer sector. The microcomputer 7 sets the transfer byte number to a predetermined register and controls the transfer of data to the host computer based on the transfer byte number.

Accordingly, in the CD-ROM system 100, the identification of the format of each sector is performed by the microcomputer 7 in accordance with a control program. However, an increase in the operating speed of the CD-ROM system 100 increases the load on the microcomputer 7. As a result, the microcomputer 7 may not be able to follow the operations of the analog signal processor 3, the digital signal processor 4, and the CD-ROM decoder 5.

### SUMMARY OF THE INVENTION

It is an object of the present invention to provide a CD-ROM decoder that decreases the load on the microcomputer, while appropriately identifying formats.

To achieve the above object, the present invention provides a CD-ROM decoder. The CD-ROM decoder temporarily stores in a buffer memory in sector units digital data having a predetermined number of bytes and a predetermined format. Further, the CD-ROM decoder processes the digital data by correcting and detecting code errors included in the digital data and transfers the processed digital data. The digital data includes header information related with a mode of a sector and sub-header information related with a form of the sector. The sub-header information includes a first code and a second code following the first code. The CD-ROM decoder includes an error flag register for receiving an error flag when an error in the digital data was not corrected during the code error correction process. A header information register stores the header information and the sub-header information. A sector information conversion circuit is connected to the error flag register and the header information register to decide the format of the digital data in each sector based on the error flag, the header information, and the sub-header information. The sector information conversion circuit also generates sector information indicating the decided format and temporarily stores the sector information and the digital data in the buffer memory. The sector information conversion circuit decides the mode of the sector of the digital data based on the header information and compares the first code and the second code to decide the form of the sector of the digital data.

Other aspects and advantages of the present invention will become apparent from the following description, taken in conjunction with the accompanying drawings, illustrating by way of example the principles of the invention.

### BRIEF DESCRIPTION OF THE DRAWINGS

The invention, together with objects and advantages thereof, may best be understood by reference to the following description of the presently preferred embodiments together with the accompanying drawings in which:

FIG. 1 is a schematic block diagram of a prior art CD-ROM system;

FIG. 2 is a diagram illustrating the structure of a sector of CD-ROM data;

FIG. 3 is a diagram illustrating formats of a sector of CD-ROM data;

FIG. 4 is a schematic block diagrams of a CD-ROM decoder according to a preferred embodiment of the present invention;

FIG. 5 is a flowchart illustrating the determination of a sector type in the CD-ROM decoder of FIG. 4; and

FIG. 6 is a table used during a sub-header comparison process.

### DETAILED DESCRIPTION OF THE PREFERRED EMBODIMENTS

In the drawings, like numerals are used for like elements throughout.

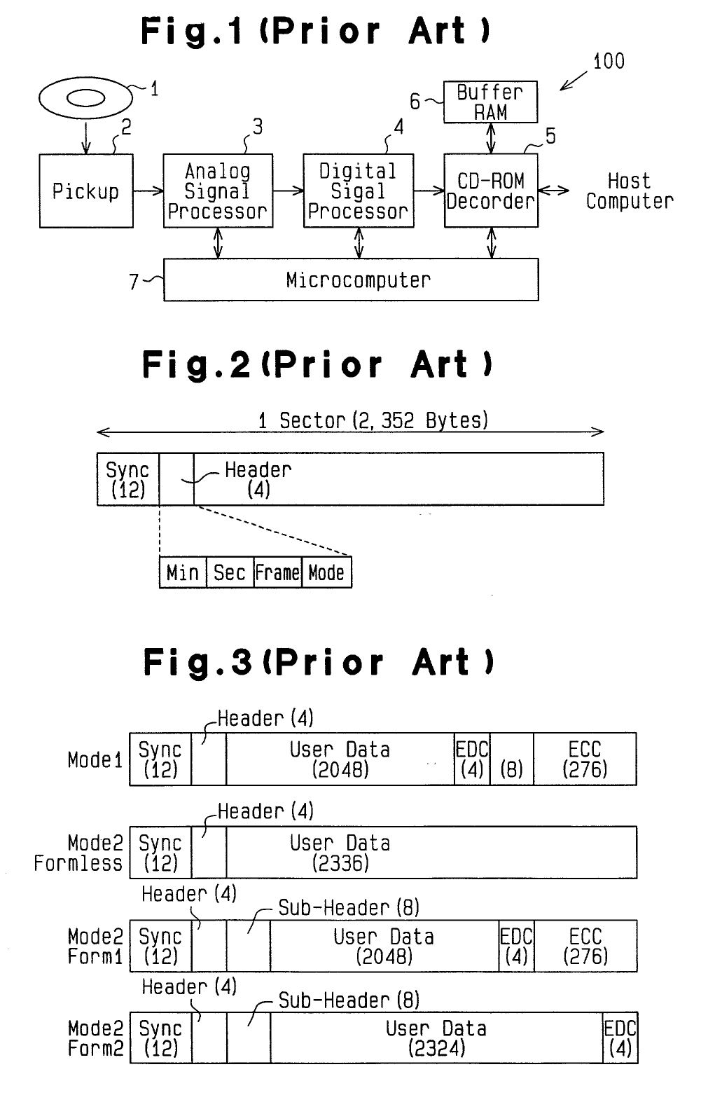

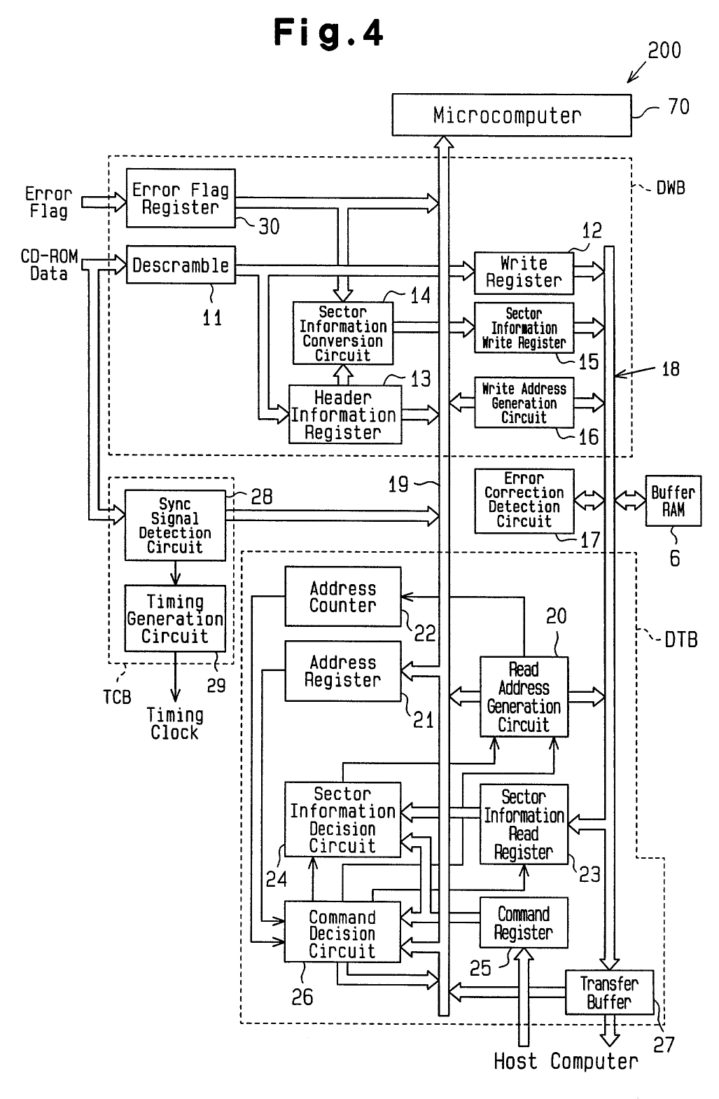

FIG. 4 shows a CD-ROM decoder 200 according to a preferred embodiment of the present invention. The CD-ROM decoder 200 is used in lieu of the CD-ROM decoder 5 of FIG. 1 and connected to the buffer RAM 6 and a microcomputer 70.

The CD-ROM decoder 200 includes a data write circuit DWB, a data transfer circuit DTB, and a timing adjustment circuit TCB. The data write circuit DWB stores CD-ROM data in the buffer RAM 6. The data transfer circuit DTB transfers the data stored in the buffer RAM 6 to a host computer. The timing adjustment circuit TCB adjusts the timing of the data write circuit DWB and the data transfer circuit DTB.

The data write circuit DWB includes a descramble circuit 11, a write register 12, a header information register 13, a sector information conversion circuit 14, a sector information write register 15, a write address generation circuit 16, and an error flag register 30.

Except for the 12 bytes of the synchronization signal, the descramble circuit 11 descrambles the 2,340 bytes of data in each sector of CD-ROM data. The descramble circuit 11 then generates descrambled CD-ROM data having a predetermined format.

The write register 12 receives CD-ROM data from the descramble circuit 11 and writes the CD-ROM data to the buffer RAM 6 via a first data bus 18.

The header information register 13 extracts 4-byte header information from the CD-ROM data provided by the descramble circuit 11 and transfers the header information to the microcomputer 70 via a second data bus 19. The header information register 13 extracts 8 bytes of data following the header as a sub-header and provides the header and the sub-header to the sector information conversion circuit 14.

The sector information conversion circuit 14 determines the mode of the CD-ROM data based on the header information. When the CD-ROM data is in mode 2, the sector information conversion circuit 14 determines the form based on the sub-header information. In accordance with the determination result, the sector information conversion circuit 14 generates 3 bits of sector information indicating the format of the CD-ROM data in each sector and provides the sector information to the sector information write register 15.

The sector information write register 15 receives the sector information from the sector information conversion circuit 14 and writes the sector information to the buffer RAM 6 via the first data bus 18.

The buffer RAM 6 has sufficient capacity for storing CD-ROM data having a predetermined number of sectors to transfer data to the host computer. The buffer RAM 6 has first sections, which store 2,352×N bytes of CD-ROM data, and second sections following the associated first sections to store N bytes of sector information. This associates the CD-ROM data and the sector information (the format information of data) in sector units in the buffer RAM 6.

The write address generation circuit 16 generates an address designating the area for a sector in one of the first sections of the buffer RAM 6 and designates a write address in the buffer RAM 6 for the CD-ROM data stored in the write register 12. The write address, which includes an address corresponding to data at the head of a sector, is provided from the write address generation circuit 16 to an address register 21 via the second data bus 19. Simultaneously, the write address generation circuit 16 generates an address designating an area having one byte in the second sections of the buffer RAM 6 and designates the write address for writing the sector information stored in the sector information write register 15 to the buffer RAM 6. The sector information write address is provided to the address register 21.

The error flag register 30 receives an error flag indicating that an error was not corrected during the error correction process and transfers the error flag to the microcomputer 70 via the second data bus 19. The error flag of the sub-header is provided to the address register 21.

The error correction detection circuit 17 corrects and detects errors in the CD-ROM data written to the buffer RAM 6. The error correction detection circuit 17 receives the CD-ROM data and sector information in single sector units from the buffer RAM 6, determines the process to be carried out on the CD-ROM data based on the sector information, corrects code errors with the ECC, and detects code errors with the EDC. For example, if the sector information is in mode 1 or in form 1 of mode 2, error correction and error detection are performed. If the sector information is form 2 of mode 2, only error detection is performed. The CD-ROM data that has undergone a predetermined process is stored again in the buffer RAM 6 to be transferred to the host computer.

The data transfer circuit DTB includes a read address generation circuit 20, the address register 21, an address counter 22, a sector information read register 23, a sector information decision circuit 24, a command register 25, the command decision circuit 26, and a transfer buffer 27.

In response to instructions from the sector information decision circuit 24 and the command decision circuit 26, the read address generation circuit 20 generates addresses designating the first and second sections of the buffer RAM 6. Based on the address, the sector information and the CD-ROM data (user data) are read from the buffer RAM 6. The read sector information is temporarily stored in the sector information read register 23. The read user data is provided to the transfer buffer 27 via the first data bus 18, and the user data is transferred to the host computer from the transfer buffer 27.

The address register 21 receives from the write address generation circuit 16 the write address corresponding to the data at the head of each sector and the write address corresponding to the sector information. Simultaneously, among the plural pieces of sector time information stored in the buffer RAM 6, the address register 21 stores the smallest piece of time information or the largest piece of time information. This enables recognition of the time information of all of the sectors stored in the buffer RAM 6.

The address counter 22 increments its count value each time the read address generation circuit 20 updates the read address and provides the count value to the command decision circuit 26. The address counter 22 is operated when the read address generation circuit 20 provides the read address to the buffer RAM 6 and counts the sector number (or the byte number) of the data read from the buffer RAM 6.

The sector information decision circuit 24 determines the format of the CD-ROM data of the sector corresponding to the sector information based on the sector information stored in the sector information read register 23. The sector information decision circuit 24 sets an offset value added to the read address by the read address generation circuit 20 in accordance with the format of the CD-ROM data when transferring data to the host computer. In other words, user data excluding the header and the sub-header is transferred to the host computer. Thus, in accordance with the format of each sector, the addresses of the header and the sub-header are added to the head address as an offset value. When all of the CD-ROM data (2,352 bytes) in a sector is transferred, offsetting is not necessary. The command decision circuit 26 determines whether offsetting is necessary based on the instruction from the host computer.

The command register 25 temporarily stores the transfer request command provided from the host computer.

The command decision circuit 26 sends operating instructions to the read address generation circuit 20 and the sector information read register 23 based on the address of the head data of each sector stored in the address register 21, the count value of the address counter 22, and the transfer request command stored in the command register 25.

The timing adjustment circuit TCB includes the synchronization signal detection circuit 28 and a timing generation circuit 29. The synchronization signal detection circuit 28 detects 12 bytes of the synchronization signal at the head of each sector of the CD-ROM data and provides the timing generation circuit 29 with a timing signal indicating the beginning of a sector. The synchronization signal detection circuit 28 provides error detection data to the microcomputer 70 via the second data bus 19 when the synchronization signal is not detected.

The timing generation circuit 29 receives the timing signal from the synchronization signal detection circuit 28 and generates various timing clock signals for determining the operating timing of the microcomputer 70, the data write circuit DWB, and the data transfer circuit DTB.

In the CD-ROM decoder 200, the data write circuit DWB and the data transfer circuit DTB are operated in accordance with the timing clock signal. Further, in response to the transfer request from the host computer, the transfer of CD-ROM data is performed automatically and not controlled by the microcomputer 70.

When the host computer requests for the transfer of a certain sector, the command decision circuit 26 refers to the address and time information held by the address register 21 to determine whether the requested sector (target sector) is stored in the buffer RAM 6. If the target sector is stored in the buffer RAM 6, the sector information read register 23 first reads the sector information corresponding to the target sector. The command decision circuit 26 then determines the format of the target sector from the read sector information.

Then, if the host computer requests for the transfer of only the user data, the command decision circuit 26 adds an offset value to the head address in accordance with the format, activates the read address generation circuit 20, and reads the user data of the target sector. For example, if the target sector is mode 1, the user data of the target sector is read from a position obtained by adding the 12 bytes of the synchronization signal and the four bytes of the header to the head address stored in the address register 21.

When the reading of the user data starts, the address counter 22 begins to count the byte number of the user data read from the buffer RAM 6. When the byte number of the read user data reaches the byte number instructed by the host computer, the command decision circuit 26 deactivates the read address generation circuit 20.

Accordingly, the data stored in the buffer RAM 6 is automatically transferred to the host computer and not controlled by the microcomputer 70.

If the CD-ROM data of the target sector is not stored in the buffer RAM 6, the command decision circuit 26 sends a new CD-ROM data read instruction to the microcomputer 70 via the second data bus 19. Then, the microcomputer 70 activates the pickup 2 and operates the analog signal processor 3, the digital signal processor 4, and the CD-ROM decoder 200 to read the CD-ROM data, which includes the target sector. After the target sector is stored in the buffer RAM 6, the above automatic transfer is performed.

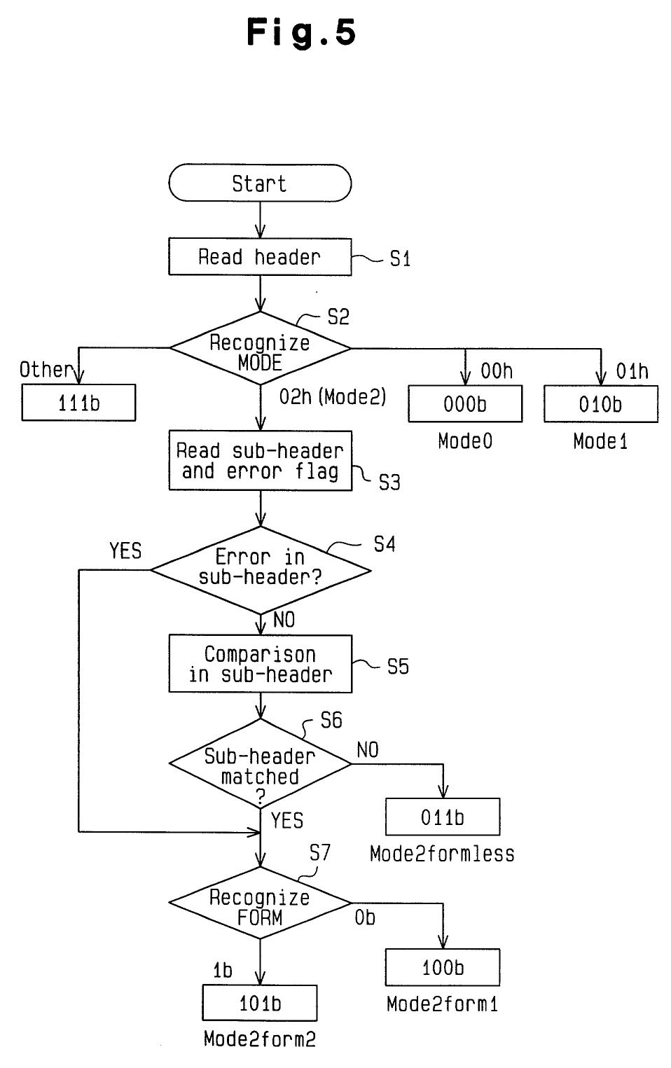

Before describing the automatic transfer of data, an operation for determining the sector information (data format) will be discussed with reference to the flowchart of FIG. 5.

The sector information conversion circuit 14 determines the sector information based on the information of the header, the sub-header, and the error flag of the sub-header. The timing generation circuit 29 adjusts the processing timing of the sector information conversion circuit 14. The sector information conversion circuit 14 includes a comparison circuit (not shown) used to detect the matching of data and a logic circuit (not shown), such as an AND circuit.

Referring to FIG. 5, at step S1, the header information register 13 provides the sector information conversion circuit 14 with the header information of the CD-ROM data.

At step S2, the sector information conversion circuit 14 recognizes the mode identification code of the header. For example, if the 1-byte mode identification code is “00h” (h indicating a hexadecimal), the sector information conversion circuit 14 sets the sector information to “000b” (b indicating a binary), which indicates mode 0. If the mode identification code is “01h”, the sector information is set to “010b”, which indicates mode 1.

If the mode identification code is “02h”, the sector information conversion circuit 14 determines that the mode is mode 2 and then proceeds to step S3. If the mode identification code is not “00h”, “01h”, or “02h”, the sector information conversion circuit 14 sets the sector information to “111b”.

At step S3, the header information register 13 provides the sector information conversion circuit 14 with the sub-header, which follows the header. Further, the sector information conversion circuit 14 is provided with the error flag of the sub-header from the error flag register 30.

At step S4, the sector information conversion circuit 14 determines whether there is an error flag in any one of the bytes of the sub-header (8 bytes). If the sub-headers include an error flag, the sector information conversion circuit 14 proceeds to step S7 and recognizes the form of mode 2 (form 1 or form 2). The determination of step S7 is performed to prevent the form of mode 2 from being erroneously recognized as formless.

When determining that the bytes of the sub-header does not include an error flag, the sector information conversion circuit 14 proceeds to step S5.

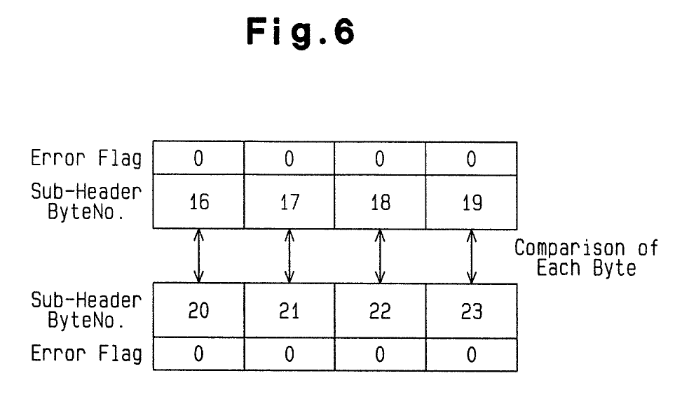

Referring to FIG. 6, at step 5, the 8 bytes of the sub-header are divided into former 4 bytes (16th to 19th bytes) and latter 4 bytes (20th to 23rd bytes). The sector information conversion circuit 14 compares the former 4 bytes to the latter 4 byes in bit units.

At step S6, the sector information conversion circuit 14 determines whether the former 4 bytes match the latter 4 bytes. Normally, the former 4 bytes match the latter 4 bytes in the sub-header. Accordingly, the sub-header is detected by detecting whether its former half and latter half are matched. When mode 2 is formless, user data exists at a location corresponding to the sub-header. In this case, the sector information conversion circuit 14 does not detect the sub-header and sets the sector information to “011b”, which indicates the formless.

If the sub-header is detected, the sector information conversion circuit 14 proceeds to step S7 and recognizes the form. A predetermined bit of the sub-header indicates form information. Thus, if the predetermined bit is “0b”, the sector information is set to “100b”, which indicates form 1 of mode 1, and if the predetermined bit is “1b”, the sector information is set to “101b”, which indicates form 2 of mode 2.

The sector information, which is 3 bits of binary data is generated through the above processing. A fixed value of 5 bits is added to the sector information, and the sector information of one byte is stored in the second section of the buffer RAM 6. The fixed value may be information other than the sector information.

The advantages of the CD-ROM decoder 200 according to the preferred and illustrated embodiment are discussed below.

(1) In the preferred embodiment, the data transfer circuit DTB performs the CD-ROM data transfer control that was performed by the prior art microcomputer 7. This decreases the number of controls and processing that were performed by the microcomputer 70, such as the recognition of the mode and form. Thus, the load on the microcomputer 70 decreases and the speed and number of transferred bytes in the microcomputer 70 increase.

(2) The determination of whether the format of the CD-ROM data is mode 2 formless or mode 2 form 1 (or form 2) is performed by simply comparing sub-header bits. Further, the determination is performed with relatively simple hardware, such as a comparison circuit.

(3) When an error flag is included in the sub-header, the form of mode 2 is determined as being form 1 or form 2. Thus, when the CD-ROM data is mode 2 form 1 or mode 2 form 2, the data is prevented from being erroneously determined as being mode 2 formless.

(4) The sector information that indicates the format of the CD-ROM data for each sector is stored in the buffer RAM together with the CD-ROM data. Accordingly, the operation of the error correction detection circuit 17 and the transfer of user data to the host computer are easily controlled by using the sector information.

It should be apparent to those skilled in the art that the present invention may be embodied in many other specific forms without departing from the spirit or scope of the invention. Particularly, it should be understood that the present invention may be embodied in the following forms.

The sector information generated by the sector information conversion circuit 14 may be stored in the buffer RAM without being transferred by way of the sector information write register 15. For example, the sector information write register 15 may be deleted, and the sector information may be transferred from the sector information conversion circuit 14 to the microcomputer 7. Alternatively, the CD-ROM decoder 200 may include a memory for storing the sector information. Such configurations also reduce the load applied to the microcomputer 70 when recognizing the format of the CD-ROM data.

When determining the data format, the following process may be performed if an error flag is included in any one of the bytes of a sub-header. For example, if an error flag is included in only the 18th byte of the sub-header of FIG. 6, subsequent to the form determination (step S7), an error correction may be performed to rewrite the data of the 18th flag with the data of the 22nd byte, which does not include an error flag. Alternatively, the comparison of the sub-header may be performed by bytes that do not include the error flag.

The present examples and embodiments are to be considered as illustrative and not restrictive, and the invention is not to be limited to the details given herein, but may be modified within the scope and equivalence of the appended claims.

What is claimed is:

1. A CD-ROM decoder for temporarily storing in a buffer memory in sector units digital data having a predetermined number of bytes and a predetermined format, processing the digital data by correcting and detecting code errors included in the digital data, and transferring the processed digital data, wherein the digital data includes header information related with a mode of a sector and sub-header information related with a form of the sector, the sub-header information including a first code and a second code following the first code, the CD-ROM decoder comprising:
an error flag register for receiving an error flag when an error in the digital data was not corrected during the code error correction process;
a header information register for storing the header information and the sub-header information; and
a sector information conversion circuit connected to the error flag register and the header information register for deciding the format of the digital data in each sector based on the error flag, the header information, and the sub-header information and generating sector information indicating the decided format, the sector information conversion circuit temporarily storing the sector information and the digital data in the buffer memory, wherein the sector information conversion circuit decides the mode of the sector of the digital data based on the header information and compares the first code and the second code to decide the form of the sector of the digital data.

2. The CD-ROM decoder according to claim 1, wherein the sector information conversion circuit refers to the sub-header information to decide the form when the first and second codes match.

3. The CD-ROM decoder according to claim 2, wherein the first code and the second code each include a plurality of sub-header codes, one of the sub-header codes being information indicating the form of the sector of the digital data, and the error flag being set to correspond with the sub-header codes, and wherein the sector information conversion circuit compares the first code and the second code and refers to the sub-header codes to decide the format when the error flag is set.

4. The CD-ROM decoder according to claim 1, wherein the first code and the second code each have a predetermined number of bytes, and wherein when one of the bytes of the first and second codes includes an error, the sector information conversion circuit corrects the byte that includes the error with a corresponding byte of the other one of the codes.

5. The CD-ROM decoder according to claim 1, wherein the format includes mode 2 formless, mode 2 form 1, and mode 2 form 2, the first code includes four bytes, and the second code includes four bytes, each corresponding to one of the four bytes of the first code, wherein the sector information conversion circuit compares the four bytes of the first code with the corresponding four bytes of the second code, decides that the format of the sector is either mode 2 form 1 or mode 2 form 2 when the first and second codes match, decides that the format is mode 2 formless when the first and second codes do not match, and decides the format when an error is included in any one of the bytes of the first and second codes by comparing the first and second codes errors at bytes excluding the one including the error and the byte corresponding to the one including the error.
